(19) United States
(12) Patent Application Publication
(10) Pub. No.: US 2026/0005209 A1
(43) Pub. Date: Jan. 1, 2026

(54) WAFER-SCALE SYSTEM-IN-PACKAGE STRUCTURE AND FORMING METHOD THEREOF

(71) Applicant: JCET Microelectronics (Jiangyin) Co. Ltd, JIANGSU (CN)

(72) Inventors: Danfeng YANG, JIANGSU (CN); Songhua XU, JIANGSU (CN); Ming HE, JIANGSU (CN); Pingping LI, JIANGSU (CN); Yao LI, JIANGSU (CN); Yaojian LIN, JIANGSU (CN)

(73) Assignee: JCET Microelectronics (Jiangyin) Co. Ltd, JIANGSU (CN)

(21) Appl. No.: 19/251,832

(22) Filed: Jun. 27, 2025

(30) Foreign Application Priority Data
Jun. 28, 2024 (CN) 202410859256.1

(51) Int. Cl. H01L 25/16; H01L 21/48; H01L 21/56; H01L 23/00; H01L 23/14; H01L 23/31; H01L 23/498; H01L 23/538

(52) U.S. Cl. CPC H01L 25/16; H01L 21/4853; H01L 21/486; H01L 21/565; H01L 23/3185; H01L 23/49811; H01L 23/5383; H01L 23/5386; H01L 23/14; H01L 24/16; H01L 24/32; H01L 24/73; H01L 2224/16227; H01L 2224/16238; H01L 2224/32225; H01L 2224/73204

(57) ABSTRACT

A wafer-scale system-in-package structure and a forming method thereof are disclosed. The package structure includes: a substrate, where the substrate includes an upper surface and a lower surface that are opposite to each other; a first molding layer that wraps the plurality of semiconductor chips and the upper surface of the substrate; external protrusions on the lower surface of the substrate; and a second molding layer that wraps side surfaces of the plurality of external protrusions and the lower surface of the substrate, where a thickness of the second molding layer is less than a thickness of the first molding layer, and at least one of the coefficient of thermal expansion or Young's modulus of the second molding layer is equal to or higher than that of the first molding layer. In this way, warpage of the system-in-package structure can be effectively controlled.

### CROSS-REFERENCE TO RELATED APPLICATION

This application claims the priority benefit of China application serial no. 202410859256.1, filed on Jun. 28, 2024. The entirety of the above-mentioned patent application is hereby incorporated by reference herein and made a part of this specification.

### TECHNICAL FIELD

The present disclosure relates to the field of semiconductor packaging, and in particular, to a wafer-scale system-in-package semiconductor package structure and a forming method thereof.

### BACKGROUND

System-in-package (SiP) is a system that integrates chips with different functions such as optoelectronics, digital/logic, radio frequency, and storage in a single package in the form of chip stacking or package stacking, so that the package can achieve the foregoing functions.

Today, the demands of emerging fields (such as mobile devices, artificial intelligence, automotive electronics, and data storage) for the amount of data computation increase exponentially. To meet the requirements of high-performance computing such as high density, high speed, high heat dissipation, low power consumption, and low latency, the existing system-in-package is expanding towards wafer scale, that is, a plurality of semiconductor chips with different functions are integrated on a silicon wafer to form a wafer-scale system-in-package structure.

Correspondingly, warpage control of the system-in-package structure has become an increasingly difficult challenge as the existing wafer-scale system-in-package structure has evolved to a super-large chiplet module.

### SUMMARY

A problem to be solved in this application is to provide a wafer-scale system-in-package structure and a forming method thereof to prevent warpage of the wafer-scale system-in-package structure, so as to effectively control warpage of the system-in-package structure with a wafer-level super-large chiplet module at room temperature or high temperature.

To solve the foregoing problem, this application provides a wafer-scale system-in-package structure, including: a substrate, where the substrate includes an upper surface and a lower surface that are opposite to each other; a plurality of semiconductor chips, where each semiconductor chip includes an active surface and a back surface that are opposite to each other, the active surfaces of the plurality of semiconductor chips are flip-chipped on the upper surface of the substrate, and the plurality of semiconductor chips are electrically connected to the substrate; a first molding layer that wraps the plurality of semiconductor chips and the upper surface of the substrate; a plurality of external protrusions on the lower surface of the substrate, where the plurality of external protrusions are electrically connected to the substrate; and forming a second molding layer that wraps the plurality of external protrusions and the lower surface of the substrate, where the second molding layer exposes the lower surfaces of the plurality of external protrusions, a thickness of the second molding layer is less than a thickness of the first molding layer, the thickness of the second molding layer is at least 15 μm, and at least one of the coefficient of thermal expansion or Young's modulus of the second molding layer is equal to or higher than that of the first molding layer.

In an optional embodiment, the substrate includes a silicon wafer, a first redistribution layer located on an upper surface of the silicon wafer, and a second redistribution layer located on a lower surface of the silicon wafer.

In an optional embodiment, the silicon wafer is provided with through-silicon vias and microdevices, the through-silicon vias are electrically connected to the first redistribution layer and the second redistribution layer, and the microdevices are electrically connected to the first redistribution layer.

In an optional embodiment, the microdevice is one or more of a high-density trench silicon capacitor, a protection diode, or a grounding inductor.

In an optional embodiment, the first molding layer exposes or wraps the back surfaces of the plurality of semiconductor chips; and a curing shrinkage rate of the second molding layer is equal to or higher than a curing shrinkage rate of the first molding layer.

In an optional embodiment, the substrate includes a middle area and an edge area surrounding the middle area, the plurality of semiconductor chips are flip-chipped on an upper surface of the middle area of the substrate, and a first passive device, a heat dissipation discrete component, or a dummy device is mounted on an upper surface of the edge area of the substrate.

In an optional embodiment, an edge of the first molding layer has chamfered trimming, arc trimming, stepped trimming, or in-edge shrinkage trimming.

In an optional embodiment, an edge of the second molding layer has chamfered trimming, arc trimming, stepped trimming, or in-edge shrinkage trimming.

In an optional embodiment, the package structure further includes a second passive device mounted on the lower surface of the substrate, where the second molding layer also wraps the second passive device.

In an optional embodiment, the second molding layer also wraps a side surface of the substrate and a side surface of the first molding layer.

In an optional embodiment, the external protrusion includes a metal pillar and a solder layer or solder joint on a lower surface of the metal pillar; or the external protrusion includes a metal ball or a metal core ball, and a solder layer or solder joint on a surface of the metal ball or metal core ball; and the solder layer or solder joint has a hemispherical surface or a coplanar flat surface, and a lower surface of the external protrusion exposed out of the second molding layer is a part of a surface of the solder layer or solder joint.

In an optional embodiment, a diagonal size of the substrate is 300±10 mm or 450±10 mm, or a diameter of the substrate is 300±5 mm or 450±5 mm.

Another embodiment of this application further provides a forming method for a wafer-scale system-in-package structure, including: providing a substrate, where the substrate includes an upper surface and a lower surface that are opposite to each other; providing a plurality of semiconductor chips, where each semiconductor chip includes an active surface and a back surface that are opposite to each other, the active surfaces of the plurality of semiconductor chips are flip-chipped on the upper surface of the substrate, and the plurality of semiconductor chips are electrically connected to the substrate; forming a first molding layer that wraps the plurality of semiconductor chips and the upper surface of the substrate; forming a plurality of external protrusions on the lower surface of the substrate, where the plurality of external protrusions are electrically connected to the substrate; and forming a second molding layer that wraps the plurality of external protrusions and the lower surface of the substrate, where the second molding layer exposes the lower surfaces of the plurality of external protrusions, a thickness of the second molding layer is less than a thickness of the first molding layer, the thickness of the second molding layer is at least 15 μm, and at least one of the coefficient of thermal expansion or Young's modulus of the second molding layer is equal to or higher than that of the first molding layer.

In an optional embodiment, the substrate includes a silicon wafer, a first redistribution layer located on an upper surface of the silicon wafer, and a second redistribution layer located on a lower surface of the silicon wafer; and the silicon wafer is provided with through-silicon vias and microdevices, the through-silicon vias are electrically connected to the first redistribution layer and the second redistribution layer, and the microdevices are electrically connected to the first redistribution layer.

In an optional embodiment, the microdevice is one or more of a high-density trench silicon capacitor, a protection diode, or a grounding inductor.

In an optional embodiment, the first molding layer exposes or wraps the back surfaces of the plurality of semiconductor chips; and a curing shrinkage rate of the second molding layer is equal to or higher than a curing shrinkage rate of the first molding layer.

In an optional embodiment, the first molding layer and the second molding layer may be formed through a compression molding or transfer molding process.

In an optional embodiment, a first grinding or first etching process is performed on an edge of the first molding layer, so that the edge of the first molding layer has chamfered trimming, arc trimming, stepped trimming, or in-edge shrinkage trimming.

In an optional embodiment, a second grinding or second etching process is performed on an edge of the second molding layer, so that the edge of the second molding layer has chamfered trimming, arc trimming, stepped trimming, or in-edge shrinkage trimming.

In an optional embodiment, the forming method further includes: mounting a second passive device on the lower surface of the substrate, where the second molding layer also wraps the second passive device.

In an optional embodiment, the second molding layer also wraps a side surface of the substrate and a side surface of the first molding layer.

In an optional embodiment, surfaces of a plurality of external protrusions that is exposed out of the second molding layer are arc-shaped surfaces or coplanar flat surfaces; the external protrusion includes a metal pillar and a solder layer located on a top surface of the metal pillar, or the external protrusion is a metal core ball, and a part of a surface of the external protrusion that is exposed out of the second molding layer is a part of the surface of the solder layer or a part of the surface of the metal core ball.

In an optional embodiment, a diagonal size of the substrate is 300±10 mm or 450±10 mm, or a diameter of the substrate is 300±5 mm or 450±5 mm.

The technical solutions of this application have the following advantages:

The wafer-scale system-in-package structure and the forming method thereof are provided in this application. The package structure includes: a substrate, where the substrate includes an upper surface and a lower surface that are opposite to each other; a plurality of semiconductor chips, where each semiconductor chip includes an active surface and a back surface that are opposite to each other, the active surfaces of the plurality of semiconductor chips are flip-chipped on the upper surface of the substrate, and the plurality of semiconductor chips are electrically connected to the substrate; a first molding layer that wraps the plurality of semiconductor chips and the upper surface of the substrate; a plurality of external protrusions on the lower surface of the substrate, where the plurality of external protrusions are electrically connected to the substrate; and a second molding layer that wraps side surfaces of the plurality of external protrusions and the lower surface of the substrate, where the second molding layer exposes the lower surfaces of the plurality of external protrusions, a thickness of the second molding layer is less than a thickness of the first molding layer, the thickness of the second molding layer is at least 15 μm, and at least one of the coefficient of thermal expansion or Young's modulus of the second molding layer is equal to or higher than that of the first molding layer. The difference between the thermal expansion coefficients or Young's moduli of the unbalanced structures or materials of the upper surface and the lower surface of the substrate is balanced or reduced by using the second molding layer of the foregoing specific properties (including a specific thickness and a specific thermal expansion coefficient or Young's modulus), to prevent warpage of the wafer-scale system-in-package structure due to the thermal expansion coefficients or Young's moduli of the unbalanced structures or materials of the upper surface and the lower surface of the substrate, so as to effectively control the warpage of the system-in-package structure with a wafer-level super-large chiplet module at room temperature or high temperature.

Further, in an embodiment, an edge of the first molding layer on an upper surface of an edge area of the substrate have chamfered trimming, arc trimming, stepped trimming, or in-edge shrinkage trimming. The edge of the first molding layer on the upper surface of the edge area of the substrate is trimmed, so that the edge of the first molding layer has chamfered trimming, arc trimming, stepped trimming, or in-edge shrinkage trimming, the size of the first molding layer on the upper surface of the edge area of the substrate is reduced, and then the difference between the Si/EMC proportion of the edge area and the Si/EMC proportion of the middle area of the upper surface of the substrate is reduced, thereby preventing warpage of the wafer-scale system-in-package structure due to a large difference between the Si/EMC proportions of the edge area and the middle area of the upper surface.

Further, in an embodiment, an edge of the second molding layer on a lower surface of an edge area of the substrate may have chamfer trimming, arc trimming, stepped trimming, or in-edge shrinkage trimming. The edge of the second molding layer on the lower surface of the edge area of the substrate is trimmed, so that the edge of the second molding layer may have chamfered trimming, arc trimming, stepped trimming, or in-edge shrinkage trimming, the size of the second molding layer on the lower surface of the edge area of the substrate is reduced, and then the difference between the Si/EMC proportion of the edge area and the Si/EMC proportion of the middle area of the lower surface of the substrate is reduced, thereby preventing warpage of the wafer-scale system-in-package structure due to a large difference between the Si/EMC proportions of the edge area and the middle area of the lower surface.

### BRIEF DESCRIPTION OF DRAWINGS

FIG. 1 and FIG. 2 are schematic diagrams of a structure of a wafer-scale system-in-package structure according to an embodiment of this application;

FIG. 3 is a schematic diagram of a structure of a wafer-scale system-in-package structure according to another embodiment of this application;

FIG. 4 is a schematic diagram of a structure of a wafer-scale system-in-package structure according to still another embodiment of this application;

FIG. 5 is a schematic diagram of a structure of a wafer-scale system-in-package structure according to still another embodiment of this application;

FIG. 6 is a schematic diagram of a structure of a wafer-scale system-in-package structure according to still another embodiment of this application;

FIG. 7 is a schematic diagram of a structure of a wafer-scale system-in-package structure according to still another embodiment of this application;

FIG. 8 is a schematic diagram of a structure of a wafer-scale system-in-package structure according to still another embodiment of this application;

FIG. 9 is a schematic diagram of a structure of a wafer-scale system-in-package structure according to still another embodiment of this application;

FIG. 10 is a schematic diagram of a structure of a wafer-scale system-in-package structure according to still another embodiment of this application;

FIG. 11 is a schematic diagram of a structure of a wafer-scale system-in-package structure according to still another embodiment of this application;

FIG. 12 is a schematic diagram of a structure of a wafer-scale system-in-package structure according to still another embodiment of this application; and

FIG. 13 is a schematic diagram of structures in a forming process for a wafer-scale system-in-package structure according to an embodiment of the present disclosure.

### DETAILED DESCRIPTION OF EMBODIMENTS

As described in the summary, an existing wafer-scale system-in-package structure is prone to warpage.

Research has shown that an existing wafer-scale system-in-package structure is large, a diagonal size or a diameter of the package structure is usually greater than or equal to 300 mm, and the large wafer-scale system-in-package structure is easy to warp, and a warpage amplitude in some areas can even reach 3 mm to 5 mm, which exceeds a processing capacity of a machine platform, makes the process unable to continue, and even results in scrapping of the package structure in serious cases. Further research has shown that the existing wafer-scale system-in-package structure includes: a silicon wafer, where the silicon wafer includes a middle area and an edge area surrounding the middle area; a plurality of semiconductor chips (or semiconductor chip modules) mounted in an array in the middle area of an upper surface of a silicon wafer; an upper molding layer that wraps the middle area and the edge area of the upper surfaces of the plurality of semiconductor chips (or semiconductor chip modules) and the upper surface of the silicon wafer; an external protrusion in the middle area of the lower surface of the silicon wafer; and a lower molding layer that wraps a side surface of the protrusion and the middle area and the edge area of the lower surface of the silicon wafer. It can be seen that the structures and materials of the upper surface and the lower surface of the silicon wafer are different. That is, the structures and materials of the upper surface and the lower surface of the silicon wafer are unbalanced, and there are large differences between the thermal expansion coefficients or the Young's moduli of the structures and materials of the upper surface of the silicon wafer and the thermal expansion coefficients or the Young's moduli of the structures and materials of the lower surface of the silicon wafer. The unbalanced the structures and materials of the upper surface and the lower surface of the silicon wafer and the large differences between the thermal expansion coefficients or the Young's moduli of the structures and materials of the upper surface of the silicon wafer and the thermal expansion coefficients or the Young's moduli of the structures and materials of the lower surface of the silicon wafer will result in warpage of the wafer-scale system-in-package structure. In addition, a large portion of the middle area of the upper surface of the silicon wafer is occupied by a material of the semiconductor chip (such as a silicon material, and the material is basically the same as that of the silicon wafer), and a small portion of the middle area is occupied by a material of the molding layer. Therefore, there is a large difference between the Si/EMC proportion of the edge area and the Si/EMC proportion of the middle area (EMC is a molding material), and the large difference between the Si/EMC proportions of the edge area and the middle area will also result in warpage of the wafer-scale system-in-package structure.

In view of this, this application provides a wafer-scale system-in-package structure and a forming method thereof to prevent warpage of the wafer-scale system-in-package structure, so as to effectively control warpage of the system-in-package structure with a wafer-level super-large chiplet module at room temperature or high temperature.

The following describes specific implementations of this application in detail with reference to the accompanying drawings. When this application is described in detail, for ease of description, schematic diagrams are not partially enlarged according to a general proportion. In addition, the schematic diagrams are merely examples and should not limit the protection scope of this application. In addition, the length, width, and depth of a three-dimensional space should be included in actual manufacture.

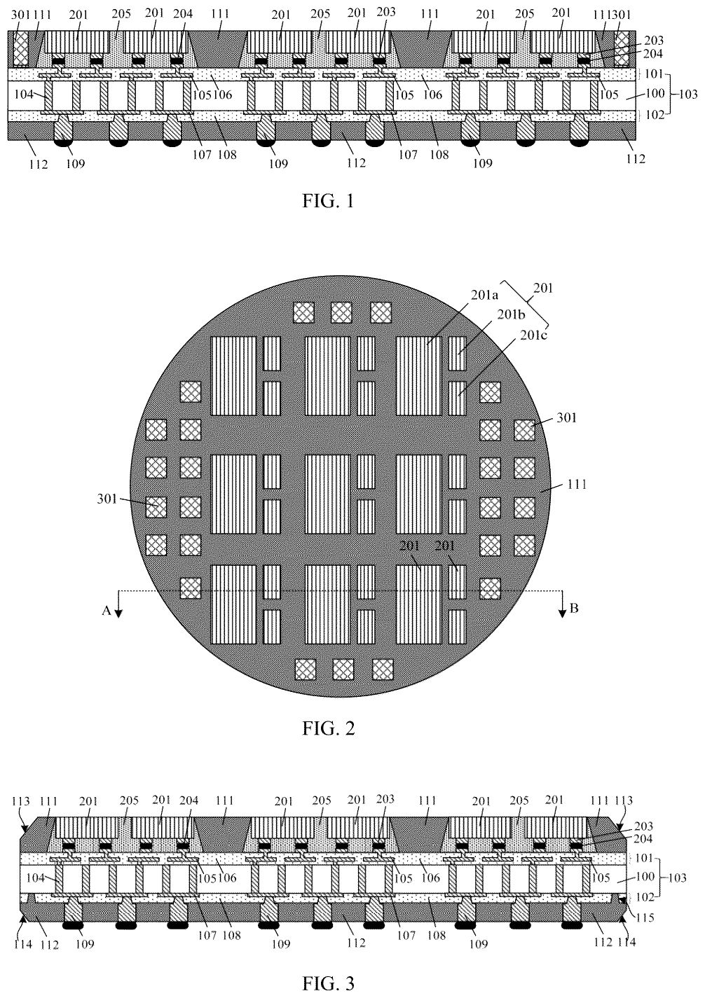

An embodiment of this application first provides a wafer-scale system-in-package structure. Referring to FIG. 1 and FIG. 2, FIG. 1 is a schematic sectional structural diagram of FIG. 2 along the AB direction. The wafer-scale system-in-package structure includes: a substrate 103, where the substrate 103 includes an upper surface and a lower surface that are opposite to each other; a plurality of semiconductor chips 201, where each semiconductor chip 201 includes an active surface and a back surface that are opposite to each other, the active surfaces of the plurality of semiconductor chips 201 are flip-chipped on the upper surface of the substrate 103, and the plurality of semiconductor chips 201 are electrically connected to the substrate 103; a first molding layer 111 that wraps the plurality of semiconductor chips 201 and the upper surface of the substrate 103, where first molding layer 111 exposes back surfaces of the plurality of semiconductor chips 201; a plurality of external protrusions 109 on the lower surface of the substrate 103, where the plurality of external protrusions 109 are electrically connected to the substrate 103; and a second molding layer 112 that wraps side surfaces of the plurality of external protrusions 109 and the lower surface of the substrate 103, where the second molding layer 112 exposes the lower surfaces of the plurality of external protrusions 109, a thickness of the second molding layer 112 is less than a thickness of the first molding layer 111, the thickness of the second molding layer 112 is at least 15 μm, and at least one of the coefficient of thermal expansion or Young's modulus of the second molding layer 112 is equal to or higher than that of the first molding layer 111.

Specifically, the substrate 103 includes a silicon wafer 100, a first redistribution layer 101 on an upper surface of the silicon wafer 100, and a second redistribution layer 102 on a lower surface of the silicon wafer 100.

A material of the silicon wafer 100 is silicon, the silicon wafer 100 may be round or square, and a corresponding shape of the substrate 103 is also round or square. In this embodiment, the package structure is a wafer-scale system-in-package structure. When the size of the wafer-scale system-in-package structure is large, sizes of the corresponding silicon wafer body 100 and substrate 103 are also large. In a specific embodiment, when the silicon wafer 100 and the substrate 103 are circular, a diameter of the silicon wafer 100 and a diameter of the substrate 103 may be 300±5 mm and 450±5 mm, respectively; and when the silicon wafer 100 and the substrate 103 are square, a diagonal size of the silicon wafer 100 and a diagonal size of the substrate 103 may be 300±10 mm and 450±10 mm, respectively.

In an embodiment, the silicon wafer 100 is provided with through-silicon vias 104 and microdevices (not shown in the figure), the through-silicon vias 104 are electrically connected to the first redistribution layer 101 and the second redistribution layer 102. In a specific embodiment, the through-silicon via 104 is located in the silicon wafer, and the through-silicon via 104 penetrates through an upper surface and a lower surface of the silicon wafer 100, an upper end of the through-silicon via 104 is electrically connected to the first redistribution layer 101, a lower end of the through-silicon via 104 is electrically connected to the second redistribution layer 102, and a material of the through-silicon via 104 is metal, which may be specifically one or more of Al, Cu, W, Au, Ag, Pt, Ni, Ti, Ta, TiN, TaN, TaC, or WAN. The microdevice is electrically connected to the first redistribution layer 101, the microdevice and the first redistribution layer 101 (and the second redistribution layer 102) cooperate to form a circuit with a specific function, where the specific function may be one or more of the decoupling and voltage stabilization, anti-static and overvoltage protection, or signal filtering of signals, and the specific function may also include other suitable functions. The microdevice may be formed inside the silicon wafer 100 or on the upper surface of the silicon wafer through a semiconductor integration manufacturing process. In an embodiment, the microdevice is one or more of a high-density trench silicon capacitor, a protection diode, or a grounding inductor, where the high-density trench silicon capacitor may be used for decoupling and voltage stabilization, the protection diode may be used for anti-static and overvoltage protection, and the grounding inductor may be used for signal filtering or isolation.

The first redistribution layer 101 is located on the upper surface of the silicon wafer 100. In an embodiment, the first redistribution layer 101 includes a first passivation layer 106 located on the upper surface of the silicon wafer 100 and a first circuit layer 105 located at the first passivation layer 106; and when the through-silicon via 104 is electrically connected to the first redistribution layer 101 and the semiconductor chip 201 is electrically connected to the substrate 103, both the through-silicon via 104 and the semiconductor chip 201 are electrically connected to a corresponding first circuit layer 105 at the first redistribution layer 101. In a specific embodiment, the first passivation layer 106 may be a single-layer or multi-layer stacked structure, and the corresponding first circuit layer 105 may also be a single-layer or multi-layer circuit layer structure. A material of the first passivation layer 106 may be an inorganic material or an organic material. The inorganic material may be one or more of silicon oxide, silicon nitride, silicon nitride, silicon carbon oxide, or silicon carbonitride; and the organic material may be a polymer resin material, which may be specifically an epoxy resin, a polyimide resin, a benzocyclobutene resin, or a polybenzoxazole resin. A material of the first circuit layer 105 is metal, which may be specifically one or more of Al, Cu, W, Au, Ag, Pt, Ni, Ti, Ta, TiN, TaN, TaC, or WN.

The second redistribution layer 102 is located on the lower surface of the silicon wafer 100. In an embodiment, the second redistribution layer 102 includes a second passivation layer 108 located on the lower surface of the silicon wafer 100 and a second circuit layer 107 located at the second passivation layer 108; and when the through-silicon via 104 is electrically connected to the second redistribution layer 102 and the external protrusion 109 is electrically connected to the substrate 103, the through-silicon via 104 and the external protrusion 109 are electrically connected to the corresponding second circuit layer 107 at the second redistribution layer 102. In a specific embodiment, the second passivation layer 108 may be a single-layer or multi-layer stacked structure, and the corresponding second circuit layer 107 may also be a single-layer or multi-layer circuit layer structure. A material of the second passivation layer 108 may be an inorganic material or an organic material. The inorganic material may be one or more of silicon oxide, silicon nitride, silicon nitride, silicon carbon oxide, or silicon carbonitride; and the organic material may be a polymer resin material, which may be specifically an epoxy resin, a polyimide resin, a benzocyclobutene resin, or a polybenzoxazole resin. A material of the second circuit layer 107 is metal, which may be specifically one or more of Al, Cu, W, Au, Ag, Pt, Ni, Ti, Ta, TiN, TaN, TaC, or WN. In a specific embodiment, the second passivation layer 108 is a double-layer stacked structure, including an inorganic material passivation layer located on the lower surface of the silicon wafer 100 and an organic material passivation layer located on a surface of the inorganic material passivation layer.

Active surfaces (facing down) of the plurality of semiconductor chips 201 are flip-chipped on the upper surface of the substrate 103, each semiconductor chip 201 includes an active surface and a back surface that are opposite to each other, a soldering protrusion 203 is arranged on the active surface, an integrated circuit with a specific function (not shown in the figure) is formed in the semiconductor chip 201, and the soldering protrusion is electrically connected to the integrated circuit. The active surfaces of the plurality of semiconductor chips 201 are flip-chipped on the upper surface of the substrate 103, and the soldering protrusions 203 on the active surfaces of the plurality of semiconductor chips 201 are soldered together with the corresponding first circuit layer 105 at the first redistribution layer 101 of the substrate 103. In an embodiment, the soldering protrusion 203 may include a solder pad and a solder layer located on a surface of the solder pad. A material of the solder pad is metal, which may be one or more of aluminum, copper, nickel, tin, titanium, tungsten, platinum, chromium, tantalum, gold, or silver. A material of the solder layer is tin or tin alloy, and the tin alloy is one or more of tin-silver, tin-zinc, tin-lead, tin-indium, tin-gold, tin-copper, tin-silver-copper, tin-silver-zinc, tin-bismuth-indium, tin-zinc-indium, or tin-silver-antimony.

Functions of the plurality of semiconductor chips 201 may be the same or different. In an embodiment, the semiconductor chip 201 includes, but is not limited to, a signal processing chip, a logic control chip, a memory chip, a sensor chip, a power supply chip, or a radio frequency chip.

In an embodiment, the substrate 103 may include a middle area and an edge area surrounding the middle area, a plurality of semiconductor chips 201 (arranged in rows and columns) are mounted on an upper surface of the middle area, or a plurality of semiconductor chip modules (arranged in rows and columns) are mounted on the upper surface of the middle area. Functions and structures of the semiconductor chip modules are the same, and each semiconductor chip module may include a plurality of semiconductor chips 201, so that distribution of an overall thermal expansion coefficient of the material of the middle area of the substrate 103 is relatively uniform, and the middle area of the substrate is not easy to be deformed. In a specific embodiment, the functions of the plurality of semiconductor chips 201 in each semiconductor chip module may be the same or different, or some functions of the semiconductor chips 201 are the same. Specifically, referring to FIG. 2, an example in which each semiconductor chip module includes three semiconductor chips 201 is used for description. Three semiconductor chips 201 flip-chipped in each semiconductor chip module may include a semiconductor chip 201a, a semiconductor chip 201b, and a semiconductor chip 201c. In an embodiment, functions of the semiconductor chip 201a, the semiconductor chip 201b, and the semiconductor chip 201c may be different. In another embodiment, functions of the semiconductor chip 201a are different from those of the semiconductor chip 201b and the semiconductor chip 201c, and the functions of the semiconductor chip 201b and the semiconductor chip 201c are the same.

In an embodiment, still referring to FIG. 1, a first passive device 301, a heat dissipation discrete component 301, or a dummy device 301 is mounted on the upper surface of the edge area of the substrate 103; and the existence of the first passive device 301, the heat dissipation discrete component 301, or the dummy device 301 reduces the amount of molding material of the first molding layer 111 on the upper surface of the edge area of the substrate 103, thereby increasing the Si/EMC proportion (EMC is a molding material, and the first passive device 301, the heat dissipation discrete component 301, or the dummy device 301 is equivalent to Si) of the edge area, so that a difference between the Si/EMC proportion of the edge area and the Si/EMC proportion of the middle area is reduced, to prevent the warpage of the wafer-scale system-in-package structure due to a large difference between the Si/EMC proportions of the edge area and the middle area, so as to effectively control the warpage of the system-in-package structure with a wafer-level super-large chiplet module at room temperature or high temperature. In a specific embodiment, when the first passive device 301 is mounted on the upper surface of the edge area of the substrate 103, the first passive device 301 is electrically connected to the substrate 103, and the first passive device 301 may be one or more of a resistor, a capacitor, or an inductor. In another specific embodiment, when the heat dissipation discrete component 301 is mounted on the upper surface of the edge area of the substrate 103, the bottom of the heat dissipation discrete component 301 is adhered to the upper surface of the edge area of the substrate 103 by using a heat dissipation adhesive, the heat dissipation discrete component 301 may be used for heat dissipation of the package structure, and a material of the heat dissipation discrete component 301 is a heat dissipation material. In another specific embodiment, when the dummy device 301 is mounted on the upper surface of the edge area of the substrate 103, the bottom of the dummy device 301 is adhered to the upper surface of the edge area of the substrate 103 by using an adhesive, and the dummy device 301 is a silicon particle without a circuit layer.

In an embodiment, there is an underfill layer 205 between the semiconductor chip 201 and the upper surface of the substrate 103. It should be noted that, in an embodiment, the underfill layer 205 can also wrap a part or all of the side walls of a corresponding semiconductor chip 201.

A plurality of external protrusions 109 are further arranged on the lower surface of the substrate 103, and the plurality of external protrusions 109 are electrically connected to the substrate 103. The external protrusions 109 are not only the connection endpoints of the package structure and an external package structure or device, but the external protrusions 109 also play the role of adjusting the thickness of the second molding layer 112 and adjusting the overall thermal expansion coefficient and Young's modulus of the material of the back surface of the substrate 103. In a specific embodiment, when the plurality of external protrusions 109 are electrically connected to the substrate 103, the external protrusions 109 are electrically connected to the second circuit layer 107 at the second redistribution layer 102 of the substrate 103.

The lower surfaces of the plurality of external protrusions 109 are exposed out of the second molding layer 112. The lower surface is a hemispherical surface (refer to FIG. 1) or a coplanar flat surface (refer to any one of FIG. 3 to FIG. 10). When the external protrusion 109 has a coplanar flat surface, the requirements of the process and subsequent soldering are satisfied, so as to ensure that soldering defects such as poor welding or short circuit will not occur.

In an embodiment, referring to FIG. 1 or any one of FIG. 3 to FIG. 9, the external protrusion 109 includes a metal pillar and a solder layer or solder joint on the top surface of the metal pillar; and the solder layer or solder joint has a hemispherical surface (refer to FIG. 1) or a coplanar flat surface (refer to any one of FIG. 3 to FIG. 10), and a lower surface of each of the plurality of external protrusions 109 exposed out of the second molding layer 112 is a surface of the solder layer or solder joint. In an embodiment, a material of the metal pillar is one or more of aluminum, nickel, tin, tungsten, platinum, copper, titanium, chromium, tantalum, gold, or silver; and a material of the solder layer or solder joint is tin or tin alloy, and the tin alloy is one or more of tin-silver, tin-indium, tin-gold, tin-copper, tin-lead, tin-silver-copper, tin-silver-zinc, tin-zinc, tin-bismuth-indium, tin-zinc-indium, or tin-silver-antimony.

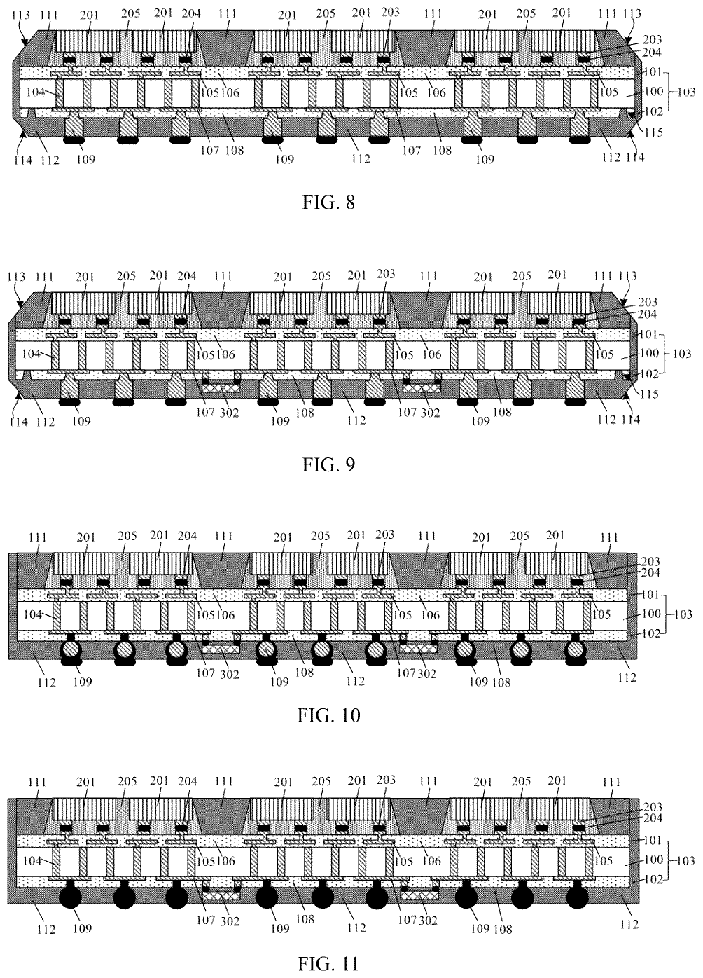

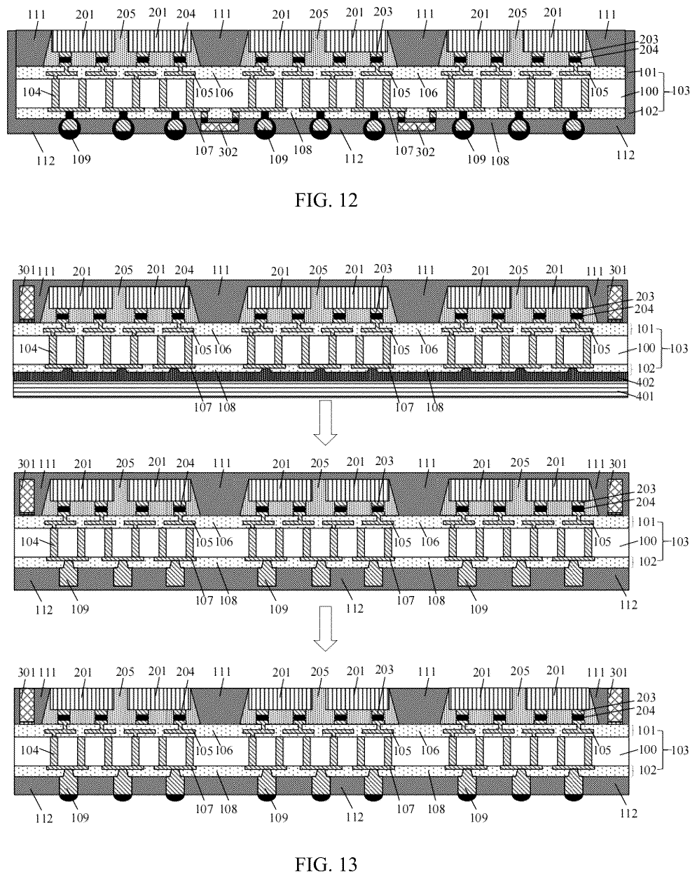

In another embodiment, referring to any one of FIG. 10 to FIG. 12, the external protrusion 109 includes a metal pillar and a solder layer or solder joint on a lower surface of the metal pillar; or the external protrusion includes a metal ball or a metal core ball, and a solder layer or solder joint on a surface of the metal ball or metal core ball; and the solder layer or solder joint has a hemispherical surface (refer to FIG. 11 or FIG. 12) or a coplanar flat surface (refer to FIG. 10), and a lower surface of the external protrusion 109 exposed out of the second molding layer 112 is a part of a surface of the solder layer or solder joint. In a specific embodiment, a material of the metal ball or the metal core ball is one or more of aluminum, copper, titanium, nickel, tungsten, platinum, chromium, tantalum, gold, or silver (refer to FIG. 10 or FIG. 12). In another specific embodiment, the material of the metal ball or the metal core ball is the same as the material of the solder layer or solder joint (refer to FIG. 11), the material of the metal ball or the metal core ball is tin or tin alloy, and the tin alloy is one or more of tin-silver, tin-indium, tin-gold, tin-copper, tin-lead, tin-silver-copper, tin-silver-zinc, tin-zinc, tin-bismuth-indium, tin-zinc-indium, or tin-silver-antimony. In an embodiment, a bottom surface of the metal ball or the metal core ball may be flat (refer to FIG. 12).

Still referring to FIG. 1, the first molding layer 111 wraps the plurality of semiconductor chips 103 and the upper surface of the substrate 103 (including the middle area and the edge area of the substrate 103). In an embodiment, referring to FIG. 1, the first molding layer 111 exposes the back surfaces of the plurality of semiconductor chips 201, and a heat sink or a heat dissipation lid may be mounted on the back surface of each semiconductor chip 201 as needed to dissipate heat of the semiconductor chip 201. In other embodiments, the first molding layer 111 may wrap (not expose) the back surfaces of the plurality of semiconductor chips 201.

The second molding layer 112 wraps side surfaces of the plurality of external protrusions 109 and the lower surface (including the middle area and the edge area of the substrate 103) of the substrate 103, where the second molding layer 112 exposes the lower surfaces of the plurality of external protrusions 109, a thickness of the second molding layer 112 is less than a thickness of the first molding layer 111, the thickness of the second molding layer 112 is at least 15 μm, and at least one of the coefficient of thermal expansion or Young's modulus of the second molding layer 112 is equal to or higher than that of the first molding layer 111. In this application, the difference between the thermal expansion coefficients or Young's moduli of the unbalanced structures or the materials of the upper surface and the lower surface of the substrate 103 is balanced or reduced by using the second molding layer 112 of the foregoing specific properties (including a specific thickness and a specific thermal expansion coefficient or Young's modulus), to prevent warpage of the wafer-scale system-in-package structure due to the thermal expansion coefficients or Young's moduli of the unbalanced structures or the materials of the upper surface and the lower surface of the substrate 103, so as to effectively control the warpage of the system-in-package structure with a wafer-level super-large chiplet module at room temperature or high temperature.

In an embodiment, at least one of the coefficient of thermal expansion or Young's modulus of the second molding layer 112 is equal to or higher than that of the first molding layer 111, and a curing shrinkage rate of the second molding layer 112 is also equal to or higher than a curing shrinkage rate of the first molding layer 111.

In an embodiment, there are many cases in which at least one of the coefficient of thermal expansion or Young's modulus of the second molding layer 112 is equal to or higher than that of the first molding layer 111. The first case is that the thermal expansion coefficient of the second molding layer 112 is equal to or higher than the thermal expansion coefficient of the first molding layer 111; the second case is that the Young's modulus of the second molding layer 112 is equal to or higher than the Young's modulus of the first molding layer 111; and the third case is that the thermal expansion coefficient and the Young's modulus of the second molding layer 112 are equal to or higher than the thermal expansion coefficient and the Young's modulus of the first molding layer 111. It should be noted that “equal” in this application is divided into two cases. The first case is that two values are numerically equal, for example, a value of the thermal expansion coefficient of the second molding layer 112 is exactly equal to a value of the thermal expansion coefficient of the first molding layer 111. The second case is that the two values are within a numerical deviation range of ±20%, for example, when a difference between the thermal expansion coefficients of the second molding layer 112 and the first molding layer 111 is within the range of ±20%, and for another example, a difference between the curing shrinkage rates of the second molding layer 112 and the first molding layer 111 is within the range of ±20%. In this application, “higher” indicates that the difference between two values is greater than 20%. For example, that the thermal expansion coefficient of the second molding layer 112 is higher than that of the first molding layer 111 means that a value of the thermal expansion coefficient of the second molding layer 112 is greater than a value of the thermal expansion coefficient of the first molding layer 111 by more than 20%. For another example, that the curing shrinkage rate of the second molding layer 112 is also higher than that of the first molding layer 111 means that a value of the curing shrinkage rate of the second molding layer 112 is greater than a value of the curing shrinkage rate of the first molding layer 111 by more than 20%.

When the edge area of the substrate 103 is narrow (which is about 3 mm and may be 1 mm to 4 mm), the edge area cannot be adjusted by arranging a functional chip (such as a passive device), a heat dissipation discrete component, a dummy device, or the like, so 100% of the edge area is molding material. In this case, the difference between the Si/EMC proportions of the edge area and the middle area is still relatively large, which results in warpage of the package structure. Therefore, in an embodiment, an edge of the first molding layer 111 on an upper surface of an edge area of the substrate 103 may have chamfer trimming, arc trimming, stepped trimming, or in-edge shrinkage trimming. The edge of the first molding layer 111 on the upper surface of the edge area of the substrate 103 is trimmed, so that the edge of the first molding layer 111 may have chamfered trimming, arc trimming, stepped trimming, or in-edge shrinkage trimming, the size of the first molding layer 111 on the upper surface of the edge area of the substrate 103 is reduced, and then the difference between the Si/EMC proportions of the edge area and the middle area of the upper surface of the substrate 103 is reduced, thereby preventing warpage in the wafer-scale system-in-package structure due to a large difference between the Si/EMC proportions of the edge area and the middle area of the upper surface.

In another embodiment, an edge of the second molding layer 112 on a lower surface of an edge area of the substrate 103 may have chamfer trimming, arc trimming, stepped trimming, or in-edge shrinkage trimming. The edge of the second molding layer 112 on the lower surface of the edge area of the substrate 103 is trimmed, so that the edge of the second molding layer 112 may have chamfered trimming, arc trimming, stepped trimming, or in-edge shrinkage trimming, the size of the second molding layer 112 on the lower surface of the edge area of the substrate 103 is reduced, and then the difference between the Si/EMC proportions of the edge area and the middle area of the lower surface of the substrate 103 is reduced, thereby preventing warpage in the wafer-scale system-in-package structure due to a large difference the Si/EMC proportions of the edge area and the middle area of the lower surface.

The edges of the first molding layer 111 and the second molding layer 112 have different trimming shapes. Specifically, in a specific embodiment, referring to FIG. 3, the edge of the first molding layer 111 has chamfered trimming 113, the edge of the second molding layer 112 has chamfered trimming 114, and the trimming amplitude of the chamfered trimming 114 of the edge of the second molding layer 112 is less than the trimming amplitude of the chamfered trimming 113 of the edge of the first molding layer 111.

In an embodiment, a blind via array 115 is further arranged at the second passivation layer 108 at the second redistribution layer 102 on the lower surface of the substrate 103 (specifically in the edge area of the organic passivation layer at the second passivation layer 108), and the second molding layer 112 is further filled with the blind via array 115. Due to the existence of the blind via array 115, more materials of the second molding layer 112 may be in contact with the lower surface of the substrate 103. This increases a contact area between the second molding layer 112 and the lower surface of the substrate 103, and then increases a tensile force of the second molding layer 112 on the lower surface of the substrate 103, thereby better offsetting or reducing an upward stress on the upper surface of the edge area of the substrate 103.

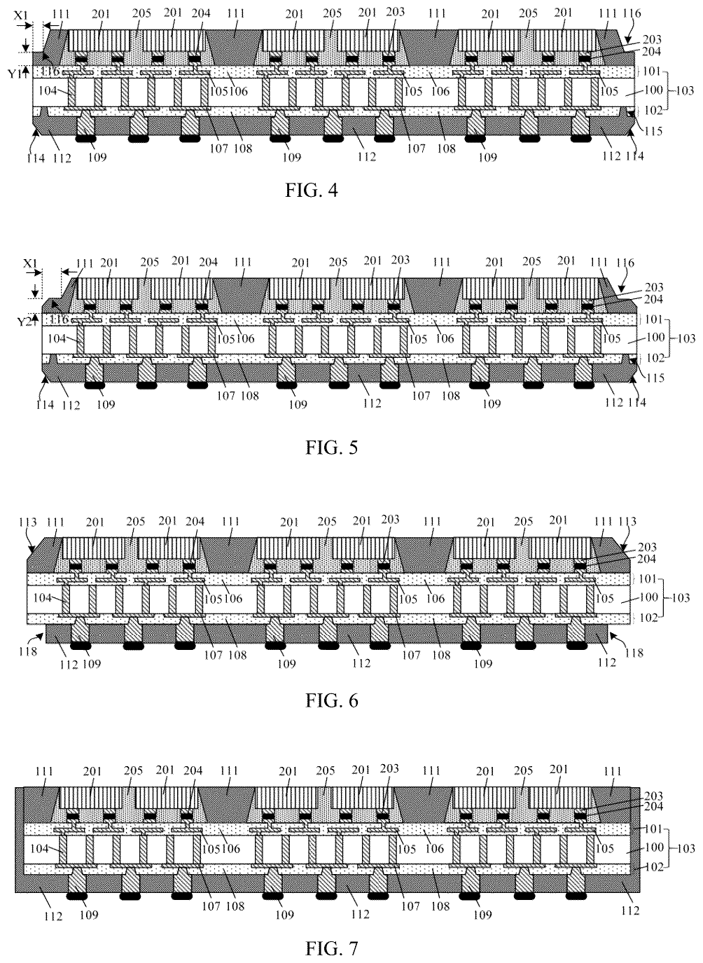

In another embodiment, referring to FIG. 4 or FIG. 5, the edge of the first molding layer 111 has stepped trimming 116, the edge of the second molding layer 112 has chamfered trimming 114, and the trimming amplitude of the chamfer trimming 114 of the edge of the second molding layer 112 is less than the trimming amplitude of the stepped trimming 116 of the edge of the first molding layer 111. The stepped trimming 116 includes at least one step, and each step includes a horizontal plane and a side surface that is connected to an outer end and tan inner end of the horizontal plane, where the side surface may be perpendicular to the horizontal plane or inccircuit layered to the horizontal plane. In a specific embodiment, referring to FIG. 4, the stepped trimming 116 includes a step, the step includes a horizontal plane, a lower side surface connected to the outer end of the horizontal plane, and an upper side surface connected to the inner end of the horizontal plane, where the lower side surface is perpendicular to the upper surface of the substrate 103 or the lower surface of the horizontal plane, the upper side surface is inclined relative to the upper surface of the horizontal plane, a vertical height Y1 of the horizontal plane and the upper surface of the substrate 103 is greater than 50 microns, and a horizontal distance X1 between the inner end of the horizontal plane and the side surface of the substrate 103 is greater than 200 microns. In another specific embodiment, referring to FIG. 5, the stepped trimming 116 includes a step, and the step includes a horizontal plane, a lower side surface connected to the outer end of the horizontal plane, and an upper side surface connected to the inner end of the horizontal plane, where the lower side surface includes a vertical plane and an inclined plane that is located above the vertical plane and that is connected to the upper end of the vertical plane, the upper end of the inclined plane is connected to the outer end of the horizontal plane, and the upper side surface is inclined relative to the upper surface of the horizontal plane, a vertical height Y2 between the horizontal plane and the upper surface of the substrate 103 is greater than 150 microns, and a horizontal distance X1 between the inner end of the horizontal plane and the side of the substrate 103 is greater than 200 microns.

In another embodiment, referring to FIG. 6, the edge of the first molding layer 111 has chamfered trimming 113, and the edge of the second molding layer 112 has in-edge shrinkage trimming 118. In a specific embodiment, a horizontal distance between an inner wall of the in-edge shrinkage trimming 118 and the side surface of the substrate 103 is greater than 200 microns.

In an embodiment, referring to FIG. 7 or any one of FIG. 10 to FIG. 12, the second molding layer 112 also wraps the side surface of the substrate 103 and the side surface of the first molding layer 111, so that the side surface of the package structure is wrapped by the molding material for protecting the package structure.

In another embodiment, referring to FIG. 8, the second molding layer 112 also wraps the side surface of the substrate 103 and the side surface of the first molding layer 111, and the edges of the first molding layer 111 and the second molding layer 112 have different trimming shapes. In a specific embodiment, the edge of the first molding layer 111 has chamfered trimming 113, and the edge of the second molding 112 has chamfered trimming 114.

In another embodiment, referring to FIG. 9, the wafer-scale system-in-package structure further includes a second passive device 302 mounted on the lower surface of the substrate 103, where the second molding layer 112 also wraps the second passive device 302. In a specific embodiment, the second passive device 302 may be one or more of a resistor, a capacitor, or an inductor.

This application further provides a forming method for a wafer-scale system-in-package structure. A specific forming process is as follows: (It should be noted that the parts of this embodiment (the forming method for a wafer-scale system-in-package structure) that are the same or similar to those in the foregoing embodiment (the wafer-scale system-in package structure) will not be repeated here; and for details, reference may be made to the limitations or descriptions in the corresponding parts in the foregoing embodiment.

Referring to the first drawing in FIG. 13, a substrate 103 is provided, where the substrate 103 includes an upper surface and a lower surface that are opposite to each other.

In an embodiment, before the process is performed on the upper surface of the substrate 103, the carrier board 401 is bonded to the lower surface of the substrate 103, and the carrier board 401 is used for support and protection. In a specific embodiment, the carrier board 401 is bonded to the lower surface of the substrate 103 through an adhesion layer.

In an embodiment, the substrate 103 includes a silicon wafer 100, a first redistribution layer 101 on the upper surface of the silicon wafer 100, and a second redistribution layer 102 on the lower surface of the silicon wafer 100. The first redistribution layer 101 includes a first passivation layer 106 and a first circuit layer 105 located at the first passivation layer 106, and the second redistribution layer 102 includes a second passivation layer 108 and a second circuit layer 107 located at the second passivation layer 108. The silicon wafer 100 has a silicon through via 104 and microdevices (not shown in the figure), where the silicon through via 104 is electrically connected to the first redistribution layer 101 and the second redistribution layer 102, and the microdevices are electrically connected to the first redistribution layer 101.

In an embodiment, the microdevice is one or more of a high-density trench silicon capacitor, a protection diode, or a grounding inductor.

In an embodiment, a diagonal size or diameter of the substrate is greater than or equal to 300 mm.

Still referring to the first drawing in FIG. 13, a plurality of semiconductor chips 201 are provided, where each semiconductor chip 201 includes an active surface and a back surface that are opposite to each other, the active surfaces of the plurality of semiconductor chips 201 are flip-chipped on the surface of the substrate 103, and the plurality of semiconductor chips 201 are electrically connected to the substrate; and a first molding layer 111 that wraps the plurality of semiconductor chips 201 and the surface of the substrate 103 is formed.

In an embodiment, still referring to the first drawing in FIG. 13, the substrate 103 includes a middle area and an edge area surrounding the middle area, the plurality of semiconductor chips 201 are flip-chipped on an upper surface of the middle area of the substrate 103, and a first passive device 301, a heat dissipation discrete component 301, or a dummy device 301 is mounted on an upper surface of the edge area of the substrate 103.

Referring to the second drawing in FIG. 13, the carrier board 401 is removed, and a plurality of metal pillars are formed on the lower surface of the substrate 103 (the metal pillar is a part of the external protrusion 109), where the plurality of metal pillars are electrically connected to the substrate 103; and a second molding layer 112 that wraps the side surfaces of the plurality of external protrusions 109 and the lower surface of the substrate 103 is formed, where a thickness of the second molding layer 112 is less than a thickness of the first molding layer 111, the thickness of the second molding layer is at least 15 μm, and at least one of the coefficient of thermal expansion or Young's modulus of the second molding layer 112 is equal to or higher than that of the first molding layer 111 Referring to the third drawing in FIG. 13, the first molding layer 111 is thinned to expose the back surface of the semiconductor chip 201, and the second molding layer 112 is thinned to expose the lower surface of the metal pillar; and a solder layer or solder joint is formed on the exposed lower surface of the metal pillar (the solder layer or solder joint is also a part of the external protrusion 109).

In another embodiment, a curing shrinkage rate of the second molding layer 112 is equal to or higher than a curing shrinkage rate of the first molding layer 111.

In an embodiment, after the first molding layer 111 and the second molding layer 112 are formed through a compression molding or transfer molding process, the first molding layer 111 and the second molding layer 112 may be thinned through a grinding process. In other embodiments, thinned first molding layer 111 and second molding layer 112 may be directly formed without an additional thinning process by using a specific mold for compression molding or transfer molding process.

In an embodiment, the following is included: a first grinding or a first etching process (or a first trimming process) is performed on the edge of the first molding layer 111, so that the edge of the first molding layer 11 has chamfered trimming 113 (refer to FIG. 3 or FIG. 6), arc trimming, stepped trimming 116 (refer to FIG. 4 or FIG. 5), or in-edge shrinkage trimming; a second grinding or a second etching process (or a second trimming process) is performed on the edge of the second molding layer, so that the edge of the second molding layer 112 has chamfered trimming 114 (refer to FIG. 3, FIG. 4, or FIG. 5), arc trimming, stepped trimming, or in-edge shrinkage shrinking trimming 118 (refer to FIG. 6).

In an embodiment, the second molding layer 112 also wraps a side surface of the substrate 103 and a side surface of the first molding layer 111 (refer to any one of FIG. 7 to FIG. 12).

In an embodiment, still referring to FIG. 13, FIG. 1, or any one of FIG. 3 to FIG. 9, the external protrusion 109 includes a metal pillar and a solder layer or solder joint on the top surface of the metal pillar; and the solder layer or solder joint has a hemispherical surface (refer to FIG. 1) or a coplanar flat surface (refer to any one of FIG. 3 to FIG. 9). When the solder layer or solder joint has a coplanar flat surface, a flattening process may be performed on the coplanar flat surface to form coining, to meet the requirements of the process and subsequent soldering, so as to ensure that a soldering defect such as poor soldering or short circuit will not occur, where the lower surface of the external protrusion 109 exposed out of the second molding layer 112 is a part of the surface of the solder layer or solder joint. In another embodiment, referring to any one of FIG. 10 to FIG. 12, the external protrusion 109 includes a metal pillar and a solder layer or solder joint on a lower surface of the metal pillar; or the external protrusion includes a metal ball or a metal core ball, and a solder layer or solder joint on a surface of the metal ball or metal core ball; and the solder layer or solder joint has a hemispherical surface or a coplanar flat surface, and a lower surface of the external protrusion exposed out of the second molding layer is a part of a surface of the solder layer or solder joint.

This application has been described with reference to the preferred embodiments, which are not used to limit this application. Those skilled in the art can make possible variations and modifications to this application using the disclosed methods and technical contents without departing from the spirit and scope of this application; and therefore, any simple modifications, equivalent changes and modifications made to the foregoing embodiments according to the technical spirit of this application without departing from the content of the technical solutions of this application shall fall within the protection scope of the technical solutions of this application.

What is claimed is:

1. A wafer-scale system-in-package structure, comprising: a substrate, wherein the substrate comprises an upper surface and a lower surface that are opposite to each other;
a plurality of semiconductor chips, wherein each semiconductor chip comprises an active surface and a back surface that are opposite to each other, the active surfaces of the plurality of semiconductor chips are flip-chipped on the upper surface of the substrate, and the plurality of semiconductor chips are electrically connected to the substrate;
a first molding layer that wraps the plurality of semiconductor chips and the upper surface of the substrate;
a plurality of external protrusions on the lower surface of the substrate, wherein the plurality of external protrusions are electrically connected to the substrate; and
a second molding layer that wraps side surfaces of the plurality of external protrusions and the lower surface of the substrate, wherein the second molding layer exposes the lower surfaces of the plurality of external protrusions, a thickness of the second molding layer is less than a thickness of the first molding layer, the thickness of the second molding layer is at least 15 μm, and at least one of the coefficient of thermal expansion or Young's modulus of the second molding layer is equal to or higher than that of the first molding layer.

2. The wafer-scale system-in-package structure according to claim 1, wherein the substrate comprises a silicon wafer, a first redistribution layer located on an upper surface of the silicon wafer, and a second redistribution layer located on a lower surface of the silicon wafer.

3. The wafer-scale system-in-package structure according to claim 2, wherein the silicon wafer is provided with through-silicon vias and microdevices, the through-silicon vias are electrically connected to the first redistribution layer and the second redistribution layer, and the microdevices are electrically connected to the first redistribution layer.

4. The wafer-scale system-in-package structure according to claim 1, wherein the first molding layer exposes or wraps the back surfaces of the plurality of semiconductor chips; and a curing shrinkage rate of the second molding layer is equal to or higher than a curing shrinkage rate of the first molding layer.

5. The wafer-scale system-in-package structure according to claim 1, wherein the substrate comprises a middle area and an edge area surrounding the middle area, the plurality of semiconductor chips are flip-chipped on an upper surface of the middle area of the substrate, and a first passive device, a heat dissipation discrete component, or a dummy device is mounted on an upper surface of the edge area of the substrate.

6. The wafer-scale system-in-package structure according to claim 1, wherein an edge of the first molding layer has chamfered trimming, arc trimming, stepped trimming, or in-edge shrinkage trimming.

7. The wafer-scale system-in-package structure according to claim 6, wherein an edge of the second molding layer has chamfered trimming, arc trimming, stepped trimming, or in-edge shrinkage trimming.

8. The wafer-scale system-in-package structure according to claim 1, further comprising: a second passive device mounted on the lower surface of the substrate, wherein the second molding layer also wraps the second passive device.

9. The wafer-scale system-in-package structure according to claim 1, wherein the second molding layer also wraps a side surface of the substrate and a side surface of the first molding layer.

10. The wafer-scale system-in-package structure according to claim 1, wherein the external protrusion comprises a metal pillar and a solder layer or solder joint on a lower surface of the metal pillar; or the external protrusion comprises a metal ball or a metal core ball, and a solder layer or solder joint on a surface of the metal ball or metal core ball; and the solder layer or solder joint has a hemispherical surface or a coplanar flat surface, and a lower surface of the external protrusion exposed out of the second molding layer is a part of a surface of the solder layer or solder joint.

11. A forming method for a wafer-scale system-in-package structure, comprising: providing a substrate, wherein the substrate comprises an upper surface and a lower surface that are opposite to each other;
providing a plurality of semiconductor chips, wherein each semiconductor chip comprises an active surface and a back surface that are opposite to each other, the active surfaces of the plurality of semiconductor chips are flip-chipped on the upper surface of the substrate, and the plurality of semiconductor chips are electrically connected to the substrate;
forming a first molding layer that wraps the plurality of semiconductor chips and the upper surface of the substrate;
forming a plurality of external protrusions on the lower surface of the substrate, wherein the plurality of external protrusions are electrically connected to the substrate; and
forming a second molding layer that wraps side surfaces of the plurality of external protrusions and the lower surface of the substrate, wherein the second molding layer exposes the lower surfaces of the plurality of external protrusions, a thickness of the second molding layer is less than a thickness of the first molding layer, the thickness of the second molding layer is at least 15 μm, and at least one of the coefficient of thermal expansion or Young's modulus of the second molding layer is equal to or higher than that of the first molding layer.

12. The forming method for a wafer-scale system-in-package structure according to claim 10, wherein the substrate comprises a silicon wafer, a first redistribution layer located on an upper surface of the silicon wafer, and a second redistribution layer located on a lower surface of the silicon wafer; and the silicon wafer is provided with through-silicon vias and microdevices, the through-silicon vias are electrically connected to the first redistribution layer and the second redistribution layer, and the microdevices are electrically connected to the first redistribution layer.

13. The forming method for a wafer-scale system-in-package structure according to claim 12, wherein the microdevice is one or more of a high-density trench silicon capacitor, a protection diode, or a grounding inductor.

14. The forming method for a wafer-scale system-in-package structure according to claim 11, wherein the first molding layer exposes or wraps the back surfaces of the plurality of semiconductor chips; and a curing shrinkage rate of the second molding layer is equal to or higher than a curing shrinkage rate of the first molding layer.

15. The forming method for a wafer-scale system-in-package structure according to claim 11, wherein the first molding layer and the second molding layer may be formed through a compression molding or transfer molding process.

16. The forming method for a wafer-scale system-in-package structure according to claim 11, wherein a first grinding or first etching process is performed on an edge of the first molding layer, so that the edge of the first molding layer has chamfered trimming, arc trimming, stepped trimming, or in-edge shrinkage trimming.

17. The forming method for a wafer-scale system-in-package structure according to claim 16, wherein a second grinding or second etching process is performed on an edge of the second molding layer, so that the edge of the second molding layer has chamfered trimming, arc trimming, stepped trimming, or in-edge shrinkage trimming.

18. The forming method for a wafer-scale system-in-package structure according to claim 11, further comprising: mounting a second passive device on the lower surface of the substrate, wherein the second molding layer also wraps the second passive device.

19. The forming method for a wafer-scale system-in-package structure according to claim 11, wherein the second molding layer also wraps a side surface of the substrate and a side surface of the first molding layer.

20. The forming method for a wafer-scale system-in-package structure according to claim 11, wherein the external protrusion comprises a metal pillar and a solder layer or solder joint on a lower surface of the metal pillar; or the external protrusion comprises a metal ball or a metal core ball, and a solder layer or solder joint on a surface of the metal ball or metal core ball; and the solder layer or solder joint has a hemispherical surface or a coplanar flat surface, and a lower surface of the external protrusion exposed out of the second molding layer is a part of a surface of the solder layer or solder joint.
